(19) United States
(12) Patent Application Publication
(10) Pub. No.: US 2026/0048455 A1
(43) Pub. Date: Feb. 19, 2026

(54) METHOD AND SYSTEM FOR SUBSTRATE ETCHING, AND SUBSTRATE HOLDER

(71) Applicant: RENA Technologies GmbH, Gütenbach (DE)

(72) Inventors: Christian SCHMITT, Gütenbach (DE); Adam HESS, Gütenbach (DE); Oliver PRUCKER, Gütenbach (DE); Nils FÜRST, Gütenbach (DE); Stefan HANSEN, Gütenbach (DE)

(21) Appl. No.: 19/102,325

(22) PCT Filed: Jul. 25, 2023
(86) PCT No.: PCT/DE2023/100545

§ 371 Date: Feb. 7, 2025

(30) Foreign Application Priority Data
Aug. 9, 2022 (DE) 10 2022 120 050.7

(51) Int. Cl. B23K 26/53; B23K 26/361; B23K 26/40; B23K 103/00; H01L 21/67

(52) U.S. Cl. CPC B23K 26/53; B23K 26/361; B23K 26/40; H01L 21/67086; B23K 2103/54

(57) ABSTRACT

A method and a system for substrate etching are disclosed, as well as a substrate holder. A substrate blank is arranged in the substrate holder and a substrate blank surface is treated with an etching medium. Prior to treatment with the etching medium, the substrate blank is irradiated with laser radiation along an outer contour of a target substrate, and therefore during treatment with the etching medium, the target substrate is separated from the substrate blank.

### FIELD

The present disclosure relates to a method and to a system for substrate etching, and to a substrate holder.

### INTRODUCTION

Etching processes are known for producing substrates with desired surface properties and/or for modifying the substrate dimensions, in particular the thickness. Typically, a large number of substrates, for example made of glass (SiO₂), are fixed in a substrate holder (carrier) and then exposed to an acidic and/or alkaline etching medium.

The problem with such etching processes is the etch marks that usually occur. These etch marks, also known as shadowing, are created by fixing the substrates in the substrate holder. In order to obtain substrates free from etch marks, complex post-treatment steps such as trimming or grinding the etched substrates are necessary.

### SUMMARY

It is an object of the present disclosure to improve the etching of substrates, in particular to enable efficient production of substrates without etch marks.

This object is achieved by a method and a system for substrate etching as well as a substrate holder, as described herein.

In a method for substrate etching according to a first aspect of the present disclosure, a substrate blank is arranged in a substrate holder and a substrate blank surface is treated with an etching medium. According to the present disclosure, the substrate blank is irradiated with laser radiation along an outer contour of a target substrate prior to treatment with the etching medium, and therefore during treatment with the etching medium, the target substrate is separated from the substrate blank, in particular automatically.

One aspect of the present disclosure is based on the approach of pretreating a substrate blank using laser radiation in such a way that the etching effect of an etching medium on the substrate blank is intensified or accelerated in one or more predetermined regions on the substrate blank surface. It is expedient to irradiate the substrate blank in such a way that a part of the substrate blank corresponding to a target substrate is or can be etched out during the etching treatment. Such etching-induced separation of the target substrate from the substrate blank enables the substrate blank to be fixed in a substrate holder without shadowing the target substrate. In other words, the substrate blank can be arranged in the substrate holder in such a way that a region of the substrate blank that corresponds to the target substrate that is later separated is not contacted by the substrate holder.

Preferably, the laser radiation is irradiated onto the substrate blank along an outer contour of the target substrate. For example, regions on the substrate blank surface can be irradiated that lie on the desired outer contour of the target substrate or together form the outer contour in a discrete manner. It has been shown that molecular bonds of the substrate material can be weakened or loosened using laser irradiation. This can make it easier for the etching medium to dissolve substrate material or components thereof in these regions. The strength of the modification of the substrate material—and thus the (local) etching effect of the etching medium—can be achieved with little effort, for example by selecting appropriate laser parameters such as wavelength, power or pulse energy, pulse duration, focus position and/or the like.

It is expedient to arrange the substrate blank in the substrate holder in such a way that the region enclosed by the outer contour is not contacted by the substrate holder. In this way, etch marks on the target substrate can be reliably and easily avoided.

Preferably, the substrate blank remains in the substrate holder until the target substrate has been separated from the substrate blank. It is expedient to end the etching treatment immediately after the target substrate has been separated. This prevents the target substrate from coming into prolonged contact with the substrate holder within the etching medium, which could result in etch marks on the target substrate.

In the following, preferred embodiments of the present disclosure and developments thereof are described which, unless expressly excluded, can be combined with each other and with the aspects of the present disclosure described below.

In a preferred embodiment, the substrate blank is irradiated with the laser radiation before it is placed in the substrate holder. This can facilitate the irradiation of the substrate blank and/or increase the precision of the irradiation.

In a further preferred embodiment, the substrate blank is irradiated with the laser radiation along the outer contour of the target substrate in such a way that, when the substrate blank is treated with the etching medium, through-holes are produced in the substrate blank along the outer contour of the target substrate. In other words, the substrate blank can be irradiated in such a way that through-holes are formed in the substrate blank during etching, which are arranged, in particular lined up, along the outer contour. It is expedient to irradiate the substrate blank with laser pulses for this purpose. This is also advantageous as it enables a particularly high energy input per unit of time to be achieved.

In the course of the etching treatment, the through-holes can continue to form. In particular, the through-holes can grow, i.e., their diameter can increase. Expediently, the etching treatment continues until adjacent through-holes join together, i.e., the material layer between two through-holes is substantially completely etched away and the target substrate is thereby separated from the substrate blank. The creation of through-holes, in particular growing through-holes, during etching allows the target substrate to be separated particularly reliably and gently.

In a further preferred embodiment, the substrate blank is irradiated with the laser radiation along the outer contour of the target substrate in such a way that, when the substrate blank is treated with the etching medium, through-holes are created in the substrate blank along the outer contour of the target substrate at a predetermined distance from one another. Expediently, adjacent through-holes connect with each other after a predetermined treatment time of the substrate blank with the etching medium. By selecting the distance between adjacent impact points, in the region of which the laser radiation strikes the substrate blank surface and the through-holes are created during etching, the desired treatment duration can be defined particularly easily.

In a further preferred embodiment, the target substrate is separated from the substrate blank without etch marks, in particular substantially without etch marks. In particular, the substrate blank can be held and/or the substrate blank surface can be irradiated and/or treated with the etching medium—for example with the aid of a correspondingly designed substrate holder—in such a way that the target substrate is separated from the substrate blank without etch marks. This eliminates the need for post-treatment aimed at removing such etch marks.

In a preferred manner, the treatment duration is adapted to the speed of an etching process on non-irradiated portions of the substrate blank surface. In particular, the treatment duration can be adapted to a desired strength of the etching treatment of the substrate blank surface in non-irradiated portions. This makes it possible to remove the target substrate from the substrate blank at a time when the etching process on the non-irradiated substrate blank surface is also completed. In other words, it is thus possible to substantially synchronize the separation of the target substrate and the end of the “conventional” etching process, for example for surface modification.

In a further preferred embodiment, the substrate holder is placed in an etching medium bath to treat the substrate blank surface with the etching medium. The substrate holder is expediently removed from the etching medium bath immediately after the target substrate has separated from the substrate blank. For example, the substrate holder can be removed from the etching medium bath immediately after the specified treatment time has been reached. This prevents the surface of the target substrate from being etched more than desired and/or prevents etch marks from forming on the separated target substrate, which may now be in contact with the substrate holder. In a further preferred embodiment, the separated target substrate is caught using the substrate holder. The substrate holder expediently has a catching device for this purpose. For example, the substrate holder can have one or more catching elements that are positioned next to and/or below the substrate blank arranged in the substrate holder. These catching elements can be designed as pins, for example. The target substrate can thus fall out of the substrate blank after it has been separated, wherein it is safely caught and guided by the catching elements.

In a further preferred embodiment, the substrate blank is held by the arrangement in the substrate holder in such a way that, when the substrate holder is aligned horizontally, the substrate blank surface is inclined relative to the vertical. In other words, the substrate blank is held at an angle in the substrate holder so that the target substrate can fall out of the substrate blank after removal. Such an arrangement of the substrate blank in the substrate holder can significantly facilitate the separation process. In particular, it can be ensured in this way that the separation is automatic and directed. This increases the efficiency of the process.

In a further preferred embodiment, the substrate blank surface is inclined at an angle of between 0° and 90° inclusive, preferably between 10° and 90° inclusive, relative to the vertical due to the arrangement of the substrate blank in the substrate holder when it is aligned horizontally. Tests have shown that this enables particularly reliable separation of the target substrate from the substrate blank. In particular, with an inclination of 10° or more, tilting of the target substrate on the remaining substrate blank, i.e., the remaining “frame”, can be reliably avoided or the risk of such tilting can at least be reduced.

In a further preferred embodiment, the laser radiation is irradiated in such a way that the target substrate separates from the substrate blank after a predetermined treatment time with the etching medium. It is expedient to select a shorter treatment time or one that is substantially equal to the time required to achieve the desired etching effect on the substrate blank surface in an unirradiated portion. This can ensure that the target substrate is separated from the substrate blank at the end of the desired etching process, for example for surface modification.

In a further preferred embodiment, the substrate blank is only irradiated with laser radiation on one side substantially perpendicular to the substrate blank surface. The penetration depth of the laser radiation into the substrate blank, and thus possibly also the depth to which a modification of the substrate material takes place with regard to an effect by the etching medium, can be set by selecting the laser parameters. Irradiating the substrate blank on only one side can speed up the process and/or reduce the laser irradiation effort.

In a further preferred embodiment, the substrate blank is irradiated with laser radiation on two opposite sides substantially perpendicular to the substrate blank surface. Here too, the penetration depth of the laser radiation can be set on both sides, if necessary independently of each other. Irradiation of the substrate blank on both sides enables targeted etching along the outer contour on both the front and rear side of the substrate blank and thus faster separation of the target substrate during treatment with the etching medium.

In a further preferred embodiment, the irradiation on the two opposite sides is carried out with different laser parameters. For example, the laser parameters can be selected in such a way that the penetration depth of the laser radiation on one side is greater than the penetration depth of the laser radiation on the opposite side of the substrate blank. This can be used to influence the treatment time required to trigger the target substrate with the etching medium. In particular, this makes it possible to control the necessary treatment time. For example, the necessary treatment time can be shortened by carrying out the etching process on both sides of the substrate.

In a further preferred embodiment, when irradiating the substrate blank with laser radiation along the outer contour of the target substrate, laser pulses strike the substrate blank surface at least in portions in the region of regularly spaced impact points. The distance can be selected here depending on the material. The distance between adjacent impact points can be, for example, 1 μm to 15 μm, preferably 2 μm to 10 μm, in particular 3 μm to 5 μm. Ideally, the impact points are in a straight line, at least in portions. This makes it possible to achieve uniform etching along the outer contour.

In principle, however, other, possibly even irregular, arrangements of the impact points are also conceivable. For example, the impact points can also run along a curved line in portions. The arrangement of the impact points can depend in particular on the substrate material and/or the geometry requirements.

In a further preferred embodiment, when the substrate blank is irradiated with laser radiation along the outer contour of the target substrate, laser pulses strike the substrate blank surface in the region of impact points, which are preferably regularly spaced at least in portions. Expediently, the impact points are located at least in portions on two or more lines running parallel to each other. Irradiating the substrate blank in this way allows the substrate material to be modified with regard to the effect of the etching medium on a larger region around the region corresponding to the target substrate. In particular, the effect of the etching medium can thus be enhanced or accelerated along a wide “band” around the target substrate. During the etching treatment, this can create a wider gap between the target substrate and the remaining substrate blank. This is particularly advantageous in the case of a thick substrate blank, as this can prevent the target substrate from tilting during separation or at least reduce the risk of tilting. In addition, the treatment time required to completely release the target substrate can also be influenced in this way.

In a further preferred embodiment, the substrate surface is treated with an etching medium containing an alkaline compound, for example potassium hydroxide (KOH), tetramethylammonium hydroxide (TMAH), sodium hydroxide (NaOH) and/or lithium hydroxide (LiOH). This allows the target substrate to be separated particularly reliably.

In particular, such an etching medium can enable particularly controlled etching—and thus controlled separation of the target substrate.

In a further preferred embodiment, the substrate blank surface is treated with the etching medium at a temperature of 90° C. or more, preferably of 110° C. or more, in particular of 120° C. or more. Particularly preferably, the substrate blank surface is treated with the etching medium at about 120° C. For this purpose, for example, an etching medium bath can be brought to such a temperature and the substrate blank can be immersed in the etching medium bath. At such a temperature, the etching medium can act reliably and in a controlled manner on the irradiated regions on the substrate blank surface. By selecting a high temperature for the etching medium, such as 110° C. or even 120° C., the etching process can be accelerated if necessary, especially compared to conventional etching processes.

It may be expedient to treat the substrate blank surface with the etching medium at a temperature between 90° C. and 190° C., preferably between 110° C. and 170° C., in particular between 120° C. and 150° C. When working in these temperature ranges, excessive vaporization of the etching medium can be avoided. In addition, heating the etching medium even more is disproportionately energy-intensive in terms of improving the etching effect.

The temperature range selected can be specific to the application or substrate. Conventional display glasses, for example, can be etched well at around 120° C. However, certain ceramic glasses, where the etching process is slower, may require correspondingly higher temperatures.

A system for substrate etching, in particular for carrying out a method according to the first aspect of the present disclosure, according to a second aspect of the present disclosure, has a laser device which is set up for irradiating a substrate blank with laser radiation along an outer contour of a target substrate in such a way that during treatment with an etching medium, the target substrate is separated from the substrate blank, in particular automatically. Furthermore, the system expediently comprises a substrate holder, in which the substrate blank can be arranged, and an etching device, which is set up to treat the irradiated substrate blank arranged in the substrate holder with the etching medium. Such a system can be used to produce substrates, for example with desired surface properties obtained by etching, which do not bear etch marks.

The laser device can, for example, have one or more solid-state lasers, such as fiber lasers. Expediently, the laser device is set up to repeatedly generate one or—synchronously—several laser pulses. Preferably, the laser device is also set up to change the position of the region in which the one or more—synchronously generated—laser pulses strike the substrate blank surface, so that the outer contour of the target substrate can be “scanned”. For this purpose, for example, at least part of an optical system of the laser device can be mounted so as to be displaceable relative to the target substrate or can be set up to influence the direction of propagation of the laser radiation.

The etching device expediently has an etching medium bath into which the substrate holder and substrate blank can be placed.

A substrate holder for holding substrate blanks, in particular for use in the method according to the first aspect of the present disclosure, according to a third aspect of the present disclosure, has a catching device which is set up to catch a target substrate separated from the substrate blank during a treatment of a held substrate blank with an etching medium. With such a substrate holder, the separated target substrate can be safely and reliably removed from the etching medium bath and post-treated, for example cleaned and/or rinsed and dried.

The present disclosure is explained in greater detail below with the aid of figures. Where appropriate, elements having the same effect are provided with the same reference signs. The present disclosure is not limited to the embodiments shown in the figures—not even with regard to functional features. The previous description and the following description of the figures contain numerous features, some of which are summarized in the dependent subordinate claims. However, a person skilled in the art will also consider these features as well as all other features disclosed above and in the following description of the figures individually and combine them to form useful further combinations. In particular, all of said features can be combined individually and in any suitable combination with the method according to the first aspect of the present disclosure, the system according to the second aspect of the present disclosure and the substrate holder according to the third aspect of the present disclosure.

### BRIEF DESCRIPTION OF THE DRAWINGS

The drawings show, at least partially schematically:

FIG. 1 an example of a substrate etching method using a corresponding system;

FIG. 2 a plan view of an example of a substrate blank irradiated with laser radiation;

FIG. 3 an example of the substrate blank from FIG. 2 irradiated with laser radiation in a cross-section;

FIG. 4 an example of an etching treatment of a substrate blank with an etching medium; and

FIG. 5 an example of a substrate holder.

### DETAILED DESCRIPTION

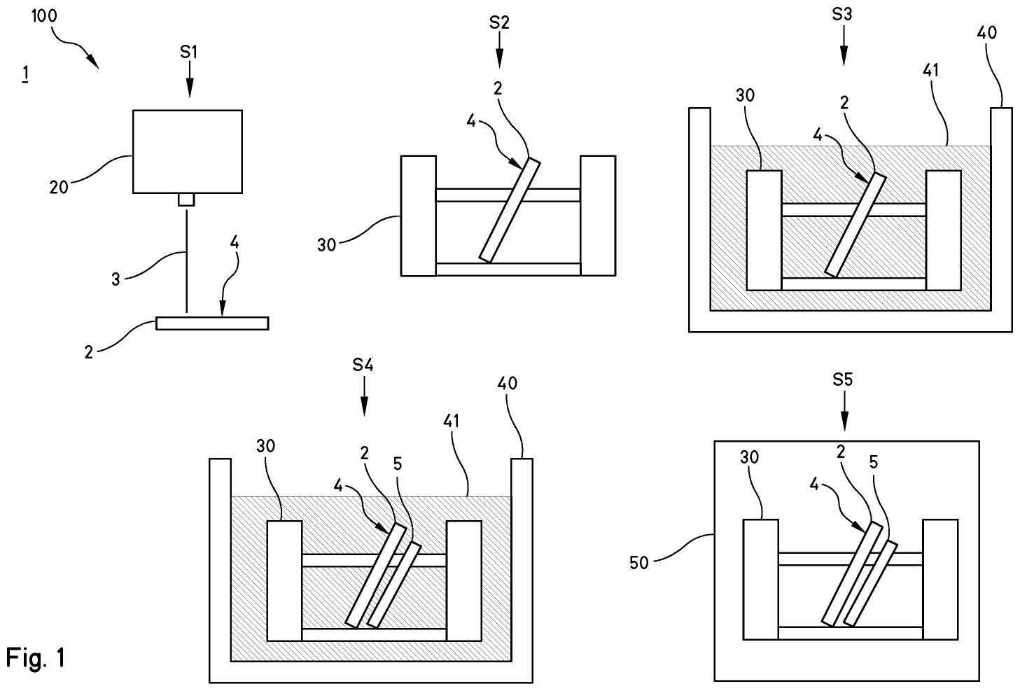

FIG. 1 shows an example of a system 1 for performing a substrate etching method 100. The system 1 has a laser device 20, a substrate holder 30, an etching device 40 and—optionally—a post-treatment device 50.

In the method 100 that can be carried out with this system 1, a substrate blank 2, such as a glass plate, is irradiated with laser radiation 3 in a method step S1. The laser device 20 is expediently used for this purpose. The laser device 20 can have any suitable laser, for example a fiber laser, to generate the laser radiation 3. The laser radiation 3 preferably comprises a plurality of laser pulses which successively strike a substrate blank surface 4.

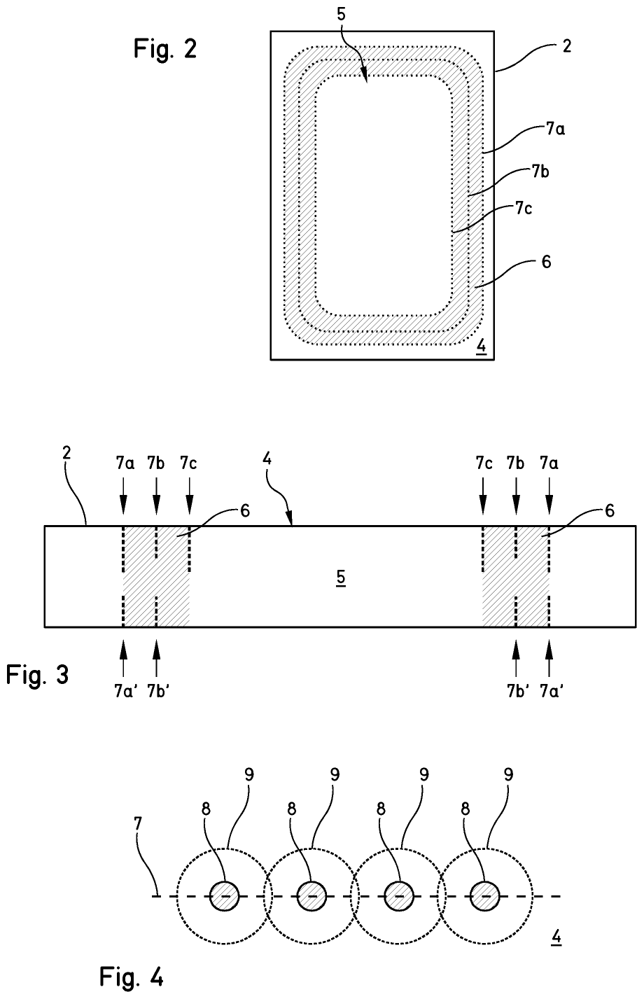

The substrate blank 2 is irradiated with the laser radiation 3, in particular the laser pulses, along an outer contour (see FIG. 2) of a target substrate 5. It is expedient for the outer contour to be successively “scanned” with the laser radiation 3, in particular the laser pulses. In other words, it is preferable if the laser radiation 3 strikes the substrate blank surface 4, for example in the region of regularly spaced impact points (see FIG. 4), wherein the position of the impact points corresponds to the outer contour. The regions in which the laser radiation 3 strikes the substrate surface 4 can therefore discretely map the outer contour.

It is expedient to irradiate the substrate blank 2 with laser radiation 3 in such a way that during treatment with an etching medium 41, the target substrate 5 is separated from the substrate blank 2. For this purpose, it may be necessary to adapt laser parameters to the properties of the substrate blank 2, for example by configuring the laser device 20. It is conceivable, for example, to adapt laser parameters to the material and/or the thickness of the substrate blank 2. Such laser parameters can, for example, relate to the power, in particular the energy per laser pulse, the pulse duration, the distance between the impact points, the wavelength and/or the like.

By irradiating the substrate blank 2 accordingly, the substrate material can be modified along the outer contour, in particular in the region of the impact points of the laser radiation 3, in such a way that the effect of the etching medium 41 is intensified and/or accelerated. In the case of substrates made of quartz glass (SiO₂) for example, the atomic bonds between silicon atoms (Si) and oxygen atoms (O) can be at least partially broken and/or weakened when irradiated at the appropriate frequency, so that the material in this region can be dissolved much more quickly by a subsequent wet chemical etching process. In particular, irradiation can promote the course of the following reactions:

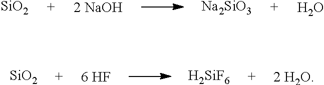

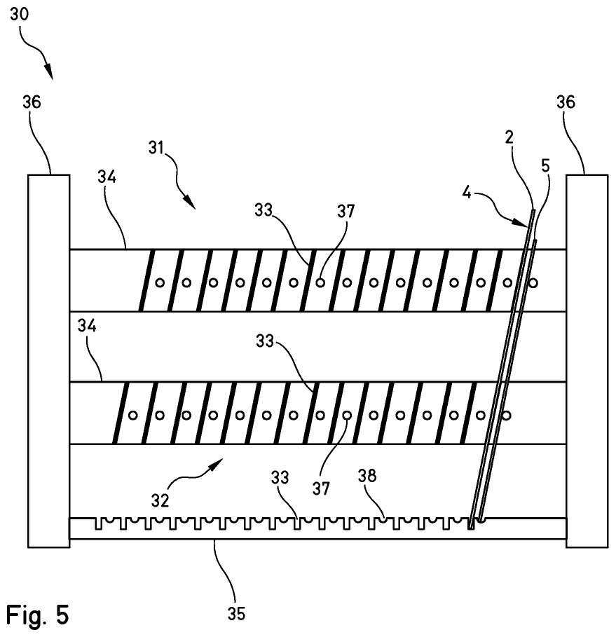

In a further method step S2, the substrate blank 2 is arranged in the substrate holder 30. For example, the substrate blank 2 can be inserted into the substrate holder 30. For this purpose, the substrate holder 30 can have a holding device, for example in the form of slots (see FIG. 5).

As indicated in FIG. 1, the substrate blank 2 is preferably held by the arrangement in the substrate holder 30 in such a way that the substrate blank surface 4 is inclined relative to the vertical when the substrate holder 30 is aligned horizontally. This can facilitate separation of the target substrate 5 from the substrate blank 2 in a further method step S3.

In this method step S3, the substrate blank surface 4 is treated with the etching medium 41, preferably using the etching device 40. The etching device 40 can have an etching medium bath consisting of the etching medium 41 for this purpose. Preferably, the substrate holder 30 together with the substrate blank 2 is immersed in the etching medium bath.

The etching medium 41 can be an alkaline or an acidic liquid. For example, potassium hydroxide (KOH), sodium hydroxide (NaOH) or hydrofluoric acid (HF) can be used to treat glass substrates.

It is preferred that the substrate blank 2 remains in the etching medium 41 for at least a predetermined treatment time. It is expedient for the etching medium 41 to have dissolved the substrate material along the outer contour, in particular in the region of the impact points of the laser radiation 3, after this treatment time has elapsed, to such an extent that a gap has formed between the target substrate 5 and the remaining substrate blank 2, the so-called “frame”. Accordingly, the target substrate 5 can separate from the substrate blank 2.

Preferably, the separated target substrate 5 is caught by the substrate holder 30 in a further, optional method step S4. For this purpose, the substrate holder 30 can have a catching device (see FIG. 5).

In a further, optional method step S5, the substrate holder 30 can be removed from the etching medium 41 together with the remaining substrate blank 2 and the separated target substrate 5. Expediently, the target substrate 5 is then cleaned, for example by rinsing with a rinsing medium. The target substrate 5 can then be dried.

The cleaning and/or drying can be carried out with the aid of the post-treatment device 50. For this purpose, the post-treatment device 50 expediently comprises a cleaning and drying chamber which can accommodate the substrate holder 30.

FIG. 2 shows a first example of a substrate blank 2 irradiated with laser radiation in a plan view, so that a substrate blank surface 4 is visible.

The substrate blank 2 was irradiated with laser radiation along an outer contour 6 of a target substrate 5 in such a way that the target substrate 5 can separate from the substrate blank 2 when treated with an etching medium. The outer contour 6 is shown hatched.

During irradiation, the laser radiation preferably strikes the substrate blank surface 4 in the region of impact points (see FIG. 4). The impact points are preferably lined up successively in a line-like manner, at least in portions, corresponding to the outer contour 6. Where the laser radiation strikes the substrate blank surface 4 and modifies the substrate material accordingly, an etching effect of the etching medium is expediently intensified or accelerated.

In the example shown, the impact points are located on three different lines 7a, 7b, 7c, which run parallel to each other in portions. Expediently, all impact points on the same line 7a, 7b, 7c are evenly spaced. The lines 7a, 7b, 7c are shown dotted, wherein each dot can be understood as an impact point.

As shown in FIG. 2, the lines 7a, 7b, 7c are preferably arranged in a nested manner, i.e., one inside the other. In other words, an outer line 7a and an inner line 7c can be provided. The inner line 7c delimits the (later) target substrate 5, while the position of the outer line 7a relative to it determines the width of a gap created between the target substrate 5 and the remaining substrate blank 2 during the etching treatment. Depending on the desired width of the gap, laser radiation can also be allowed to strike the substrate blank surface 4 between the outer and inner lines 7a, 7c, as in the present example, in order to enable the gap to form evenly. The corresponding impact points can, as in the present example, be located on a line 7b or also on several other lines. In principle, however, it is also possible to irradiate the substrate blank 2 in such a way that laser radiation only strikes the substrate blank surface 4 in the region of impact points that are located on only two different lines 7a, 7c or even on only one line 7a.

FIG. 3 shows a cross-section of an example of the substrate blank 2 from FIG. 2 irradiated with laser radiation. Various irradiation options are illustrated here purely for the purpose of explanation.

On the one hand, it is possible to irradiate the substrate blank 2 with laser radiation on one side only. This is indicated by the dashed line, which illustrates the penetration depth of laser radiation in the region of impact points that lie on the inner line 7c delimiting the target substrate 5.

The term “penetration depth” refers here in particular to a depth or depth range at which the laser radiation interacts particularly strongly with the substrate material. In other words, “penetration depth” expediently refers to the depth or depth range at which the substrate material is modified in such a way that the etching effect of the etching medium is intensified or accelerated.

The penetration depth can be adjusted by selecting appropriate laser parameters, for example by adjusting the wavelength, the power or pulse energy, the pulse duration and/or the like, in particular the focus position or focus depth in relation to the substrate blank surface 4.

On the other hand, it is possible to irradiate the substrate blank 2 on two opposite sides, i.e., both on the front and on the rear side. Such two-sided irradiation is indicated by the dashed lines, which illustrate the penetration depth of laser radiation in the region of impact points that lie on the middle line 7b or on the outer line 7a, on the one hand, and on opposite lines 7b′, 7a′, on the other hand, which correspond to them.

With two-sided irradiation, it is generally possible to carry out symmetrical irradiation (see lines 7b, 7b′). However, asymmetrical irradiation is also conceivable (see lines 7a, 7a′). With such asymmetrical irradiation, the penetration depth of the laser radiation on one side can be greater than the penetration depth on the other, opposite side.

As shown in FIG. 3, the various irradiation options can be used together. However, it is also conceivable to irradiate exclusively on one or two sides and—in the case of two-sided irradiation—exclusively symmetrically or asymmetrically.

By irradiating along two or more lines 7a, 7b, 7c, which run parallel at least in portions, the treatment time required to release the target substrate can be influenced in particular. In principle, at least up to a certain limit, a faster separation of the target substrate from the substrate blank can be achieved with an increasing number of lines—i.e., with a wider gap. Alternatively or additionally, the treatment time can also be influenced by the selected penetration depth(s) of the laser radiation.

FIG. 4 shows an example of an etching treatment of a substrate blank with an etching medium. The substrate blank was irradiated with laser radiation prior to the etching treatment. As a result, the substrate material in the regions 8 shown hatched, in which the laser radiation strikes a substrate blank surface 4, is suitably modified in such a way that the etching effect of the etching medium is intensified or accelerated. During the etching treatment, the substrate material is dissolved to a correspondingly greater extent in the regions 8. In this way, through-holes 9 can form in the substrate blank in the regions 8.

As the treatment of the substrate blank with the etching medium progresses, the through-holes 9 grow in size. In other words, the through-holes 9 can increasingly expand. This is indicated in FIG. 4 by the dotted circles. Depending on the distance between adjacent impact points, in the region 8 of which the laser radiation strikes the substrate blank surface 4, adjacent through-holes 9 can join together sooner or later. In other words, as the etching treatment progresses, the material layer between adjacent through-holes 9 substantially dissolves completely.

This mechanism expediently leads to the formation of a gap between the remaining substrate blank and a target substrate of which the outer contour corresponds to the lined-up arrangement of the impact points. Accordingly, the target substrate can separate from the substrate blank.

In the example shown in FIG. 4, the impact points are arranged regularly on the substrate blank surface 4. In particular, the impact points are located here on a dashed line 7 and have a predetermined distance to the respective adjacent impact points. The regions 8 around the impact points, in which the laser radiation strikes the substrate blank surface 4, are arranged correspondingly regularly, and the through-holes 9 are also formed correspondingly regularly.

The treatment duration required to connect the through-holes 9 and the associated separation of the target substrate can be specified in particular by selecting the distance between adjacent impact points or regions 8. In this respect, the treatment duration can be adjusted to a desired effect of the etching medium on portions of the substrate blank surface 4 that are not irradiated with laser radiation—i.e., are unmodified. In other words, the treatment duration can be adjusted by specifying the distance between adjacent impact points or regions 8 so that the target substrate dissolves in unmodified portions of the substrate blank substantially at the same time as the desired etching effect is achieved.

FIG. 5 shows a side view of an example of a substrate holder 30. The substrate holder 30 has a holding device 31 for holding substrate blanks 2 and a catching device 32 for catching target substrates 5 separated from the substrate blanks 2 during treatment with an etching medium. For reasons of clarity, only one substrate blank 2 and one target substrate 5 are shown.

The holding device 31 is preferably designed in such a way that held substrate blanks 2 are not contacted in a region corresponding to the target substrate 5 to be separated. For this purpose, the holding device 31 expediently has a plurality of slots 33 into which the substrate blanks 2 can be inserted. As a result, contact of the substrate holder 30 with the substrate blanks 2 can be limited to a narrow strip at the edge of the substrate blanks 2. For example, the substrate blanks 5 can be inserted into the slots in such a way that contact of the substrate holder (30) with the substrate blanks (2) is limited to a portion that lies outside a region corresponding to the target substrate (5) to be separated. The region corresponding to the target substrate 5 to be separated remains unaffected (see FIG. 2). For reasons of clarity, only some of the slots 33 are provided with a reference sign in the present case.

The slots 33 are expediently provided in at least one—in the present example two—crossmembers 34, which are arranged between two side walls 36 of the substrate holder 30. In the case of two or more crossmembers 34, two of the slots 33 in different crossmembers 34 are aligned with each other, so that exactly one substrate blank 2 can be arranged in these two slots 33.

The holding device 31 is expediently designed to hold the substrate blanks 2 in such a way that, when the substrate holder 30 is aligned horizontally, a substrate blank surface 4 is inclined relative to the vertical. For this purpose, the slots 33 can be provided at a corresponding angle in the crossmembers 34. Preferably, the slots 33 are aligned in such a way that an inclination of the substrate blank surface 4 relative to the vertical of more than 0°, preferably 10° or more, but at most 90° is achieved.

The substrate holder 30 also has a bridge 35, on which the substrate blanks 2, held in particular in the slots 33 of the holding device 31, can be placed with a lower end. The bridge 35 also connects the side walls 36. Preferably, the bridge 35 also has slots 33, as shown in FIG. 5, so that the ends of the substrate blanks 2 can also be fixed when arranged in the slots 33 of the crossmembers 34.

If necessary, several bridges 35 and crossmembers 34 can also be arranged one behind the other, i.e., in a direction perpendicular to the plane of the figure, in order to increase the capacity of the substrate holder 30.

The catching device 32 preferably has a large number of catching elements 37, only some of which are provided with reference signs for reasons of clarity. In the present example, the catching elements 37 are designed as pins that project horizontally from at least one, in this case both, crossmembers 34. The catching elements 37 are expediently arranged adjacent to the slots 33. One catching element 37 can be provided for each slot 33 and crossmember 34. In other words, one catching element 37 can be assigned to each slot 33 in a crossmember 34. In principle, however, several catching elements 37 per slot 33 are also conceivable.

After separation from the substrate blank 2, the target substrate 5 can thus fall with one lower end onto the bridge 35, while it is held laterally by the catching elements 37.

Expediently, the bridge 35 has a plurality of recesses 38, each of which is designed to fix a separated target substrate 5. A fixation here is in particular a stabilization of the position of the separated target substrate 5 in the horizontal plane. In other words, the fixation can prevent or at least impede movement along the bridge 35, in particular of an end of the target substrate 5 facing the bridge 35.

The recesses 38 can be designed, in particular arranged, in such a way that a target substrate 5 removed from the substrate blank 2 slides, in particular automatically, into one of the recesses 38. For this purpose, a respective recess 38 can be provided adjacent to a slot 33 in the bridge 35.

### LIST OF REFERENCE SIGNS

1 system
2 substrate blank
3 laser radiation
4 substrate blank surface
5 target substrate
6 outer contour
7 line
7a outer line
7a′ outer line
7b middle line
7b′ middle line
7c inner line
8 region
9 through-hole
20 laser device
30 substrate holder
31 holding device
32 catching device
33 slot
34 crossmember
35 bridge
36 side wall
37 catching element
38 recess
40 etching device
41 etching medium
50 post-treatment device
100 method
S1-S5 method steps

1. A method for substrate etching, the method comprising:
arranging a substrate blank in a substrate holder;
treating a surface of the substrate blank with an etching medium;
prior to treatment with the etching medium, irradiating the substrate blank with laser radiation along an outer contour of a target substrate; and
during treatment with the etching medium, separating the target substrate from the substrate blank.

2. The method as claimed in claim 1, wherein irradiating the substrate blank with the laser radiation along the outer contour of the target substrate includes irradiating in a way configured such that, when the substrate blank is treated with the etching medium, through-holes are produced in the substrate blank along the outer contour of the target substrate.

3. The method as claimed in claim 1, wherein irradiating the substrate blank with the laser radiation along the outer contour of the target substrate includes irradiating in a way configured such that, during the treatment of the substrate blank with the etching medium, through-holes are produced in the substrate blank along the outer contour of the target substrate at a predetermined distance from one another and, after a predetermined treatment time of the substrate blank with the etching medium, adjacent through-holes connect with each other.

4. The method as claimed in claim 1, wherein the target substrate is separated from the substrate blank substantially free from etch marks.

5. The method as claimed in claim 1, further comprising:
introducing the substrate holder for treating the substrate blank surface with the etching medium into an etching medium bath; and
removing the substrate holder from the etching medium bath immediately after the target substrate has separated from the substrate blank.

6. The method as claimed in claim 1, further comprising catching the separated target substrate with the aid of the substrate holder.

7. The method as claimed in claim 1, further comprising holding the substrate blank by the arrangement in the substrate holder such that the substrate blank surface is inclined relative to the vertical when the substrate holder is aligned horizontally.

8. The method as claimed in claim 7, wherein the substrate blank surface is inclined relative to the vertical by an angle between 0° and 90° inclusive.

9. The method as claimed in claim 1, wherein the substrate blank is irradiated with laser radiation on one side substantially perpendicular to the substrate blank surface.

10. The method as claimed in claim 1, wherein the substrate blank is irradiated with laser radiation on two opposite sides substantially perpendicular to the substrate blank surface.

11. The method as claimed in claim 1, wherein the irradiating is carried out on the two opposite sides with different laser parameters.

12. The method as claimed in claim 1, wherein irradiating the substrate blank with laser radiation along the outer contour of the target substrate comprises striking the substrate blank surface with laser pulses at least in portions in a region of regularly spaced impact points, wherein the impact points lie on a line.

13. The method as claimed in claim 1, wherein irradiating the substrate blank with laser radiation along the outer contour of the target substrate comprises striking the substrate blank surface with laser pulses in a region of impact points, wherein the impact points lie at least in portions on two or more lines running parallel to one another.

14. The method as claimed in claim 1, wherein irradiating the substrate blank with laser radiation along the outer contour of the target substrate comprises striking the substrate blank surface with laser pulses in a region of impact points, wherein the impact points lie at least in portions on two or more lines arranged in a nested manner and on an inner line delimiting the target substrate.

15. The method as claimed in claim 1, wherein the etching medium contains potassium hydroxide, tetramethylammonium hydroxide, sodium hydroxide, and/or lithium hydroxide.

16. The method as claimed in claim 1, wherein the substrate blank surface is treated with the etching medium at a temperature of 90° C. or more.

17. The method as claimed in claim 1, wherein the substrate holder has a catching device configured to catch a target substrate separated from the substrate blank during a treatment of a held substrate blank with an etching medium.

18. The method as claimed in claim 17, wherein the substrate holder has a holding device for holding substrate blanks, which has a plurality of slots for inserting the substrate blanks such that contact of the substrate holder with the substrate blanks is limited to a portion which lies outside a region corresponding to the target substrate to be separated.

19-20. (canceled)

21. The method as claimed in claim 17, wherein the substrate holder has two side walls and a bridge between the two side walls, wherein lower ends of the substrate blanks can be placed on the bridge and/or on which separated target substrates can fall with a lower end.

22. The method as claimed in claim 21, wherein the bridge comprises a plurality of recesses, each of which is formed to stabilize a separated target substrate wherein the recesses are configured such that a target substrate separated from the substrate blank automatically slides with its lower end into one of the recesses.

23-24. (canceled)
